(19) United States
(12) Patent Application Publication
(10) Pub. No.: US 2016/0212894 A1
(43) Pub. Date: Jul. 21, 2016

(54) DISPLAY DEVICE

(71) Applicant: Innolux Corporation, Miao-Li County (TW)

(72) Inventors: Wei-Jen Tsai, Miao-Li County (TW); Hui-Lang Lee, Miao-Li County (TW); Ying-Wen Yang, Miao-Li County (TW)

(21) Appl. No.: 14/991,432

(22) Filed: Jan. 8, 2016

(30) Foreign Application Priority Data
Jan. 20, 2015 (TW) 104101821

(51) Int. Cl. H05K 9/00; H05K 5/00; H05K 1/02; H05K 5/04

(52) U.S. Cl. CPC H05K 9/0054; H05K 5/04; H05K 5/0026; H05K 5/0017; H05K 1/0216; H05K 9/0067; H05K 1/0259; H05K 2201/10128

(57) ABSTRACT

A display device includes a display panel, a circuit board, and a conductive element. The circuit board is adjacent to the display panel and electrically connected to the display panel. The circuit board has at least a conductive pattern configured at a ground zone, and the conductive pattern has a plurality of conductive portions spaced apart each other. The quantities of the conductive portions respectively arranged along a first direction and a second direction are plural, and the first direction is substantially perpendicular to the second direction. The conductive element is disposed on the conductive pattern, and the conductive element is electrically connected to the conductive portions.

### CROSS REFERENCE TO RELATED APPLICATIONS

This Non-provisional application claims priority under 35 U.S.C. §119(a) on Patent Application No(s). 104101821 filed in Taiwan, Republic of China on Jan. 20, 2015, the entire contents of which are hereby incorporated by reference.

### BACKGROUND OF THE INVENTION

1. Field of Invention

The invention relates to a display device and, in particular, to a display device with a PCB.

2. Related Art

With the advance of technology, flat display devices have been broadly applied to various fields and especially to liquid crystal display devices or organic light emitting diode display devices. Because flat display devices have superior characteristics of thin and light body, low power consumption, and no radiation, they gradually replace conventional cathode ray tube display devices and are applied to various electronic products, such as mobile phones, portable media devices, laptops, televisions, and so on.

Moreover, because of more powerful functions, faster operating speed, and increasingly dense and complex electronic circuits of modern electronic products, the problem of electromagnetic interference (EMI) or electrostatic discharge (ESD) becomes a major challenge of circuit design. Therefore, how to improve the protection of electronic circuits from EMI noise and ESD is a target pursued in this field.

In conventional technology, in the product development processes of display devices, an adhesive conductive element (e.g. conductive foam) is disposed on a control circuit board generally, so that the element on the circuit board may directly contact the metal case through the conductive element to improve the protection of the element from EMI and ESD. However, the conductive element on the circuit board by adhesion not only increases working-hours for adhesion but also results in poor contact, peeling off, or other problems of the conductive element, so the protection against EMI or ESD is reduced.

### SUMMARY OF THE INVENTION

An objective of the invention is to provide a display device which can improve the adhesion of the conductive element.

To achieve the above objective, a display device according to the invention includes a display panel, a circuit board, and a conductive element. The circuit board is adjacent to the display panel and electrically connected to the display panel. The circuit board has at least a conductive pattern configured at a ground zone, and the conductive pattern has a plurality of conductive portions spaced apart each other. The quantities of the conductive portions respectively arranged along a first direction and a second direction are plural, and the first direction is substantially perpendicular to the second direction. The conductive element is disposed on the conductive pattern, and the conductive element is electrically connected to the conductive portions.

In one embodiment, the conductive portions are arranged in a two-dimensional matrix.

In one embodiment, at least a part of the conductive portions are directly connected to the conductive element by welding.

In one embodiment, the conductive element has an elastic body and a metal layer, and the metal layer is disposed on an outer surface of the elastic body.

In one embodiment, the conductive element has a first surface, the first surface contacts the conductive pattern, and the sum of the lengths of the conductive portions along the first direction is 0.5 to 0.85 times of the length of the first surface along the first direction.

In one embodiment, an interval between two adjacent conductive portions along the first direction is larger than 0.5 mm and smaller than 1.2 mm.

In one embodiment, at least one of the conductive portions is partially exposed outside the conductive element in the first direction.

In one embodiment, the conductive portions are completely covered with the conductive element in the second direction.

In one embodiment, the display device further includes a metal element. The conductive element has a first surface and a second surface opposite to the first surface, the first surface contacts the conductive portions, and the second surface contacts the metal element.

In one embodiment, the metal element is a case, a frame or a backplane of the display device.

As mentioned above, in the display device according to the invention, the quantities of the conductive portions which are spaced apart each other and located at the ground zone of the circuit board respectively along the first direction and the second direction are plural, and the conductive element is disposed on the conductive pattern and electrically connected to the conductive portions. Thus, compared with conventional technology, it can reduce the ground impedance of the conductive element and the ground zone and improve the durability of the conductive element against the stress due to the lateral force. Therefore, it can avoid poor contact, separation, or other problems of the conductive element so as to improve the protection of the display device from EMI and ESD.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram of a display device according to an embodiment of the invention;

FIG. 2A is a schematic diagram of the connection between the circuit board and the conductive element of the display device in FIG. 1;

FIG. 2B is a top view of the conductive pattern on the circuit board in FIG. 2A;

FIG. 2C is a schematic diagram of the connection of the circuit board, the conductive element, and a metal element in the display device;

FIG. 3A is a schematic diagram of the connection between the circuit board and the conductive element of another embodiment; and

FIG. 3B is a top view of the conductive pattern on the circuit board in FIG. 3A.

### DETAILED DESCRIPTION OF THE INVENTION

The present invention will be apparent from the following detailed description, which proceeds with reference to the accompanying drawings, wherein the same references relate to the same elements.

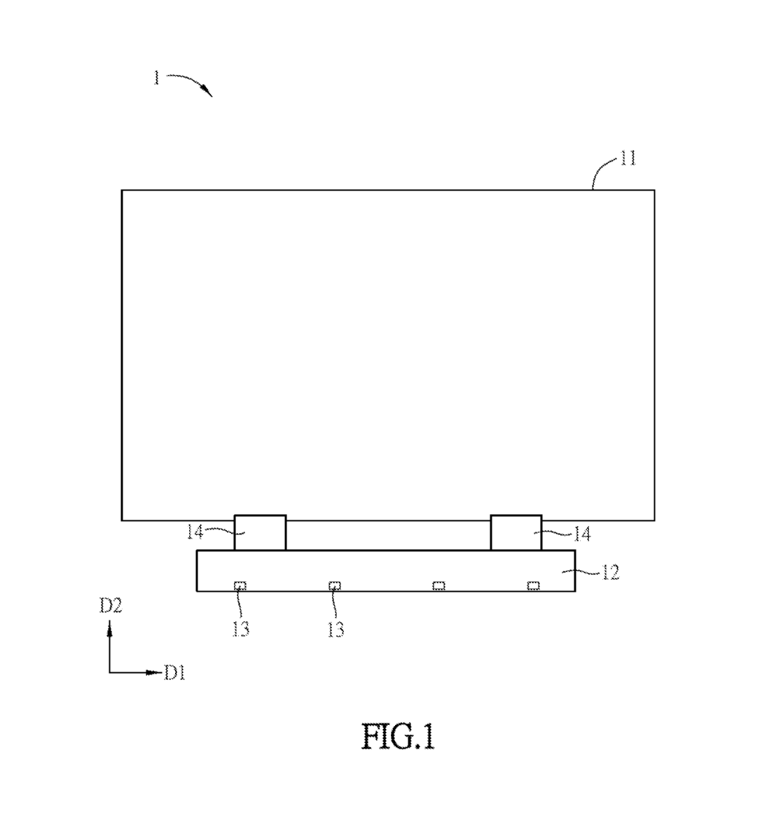

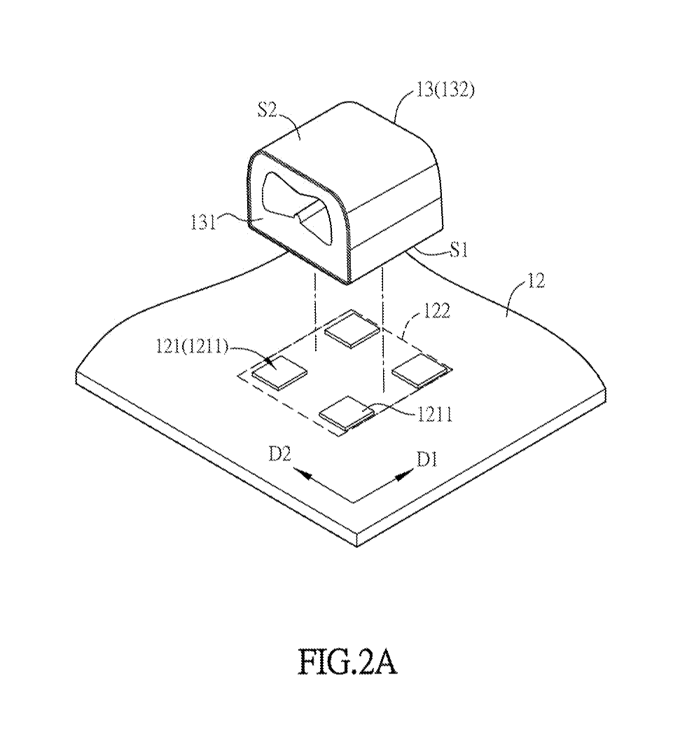

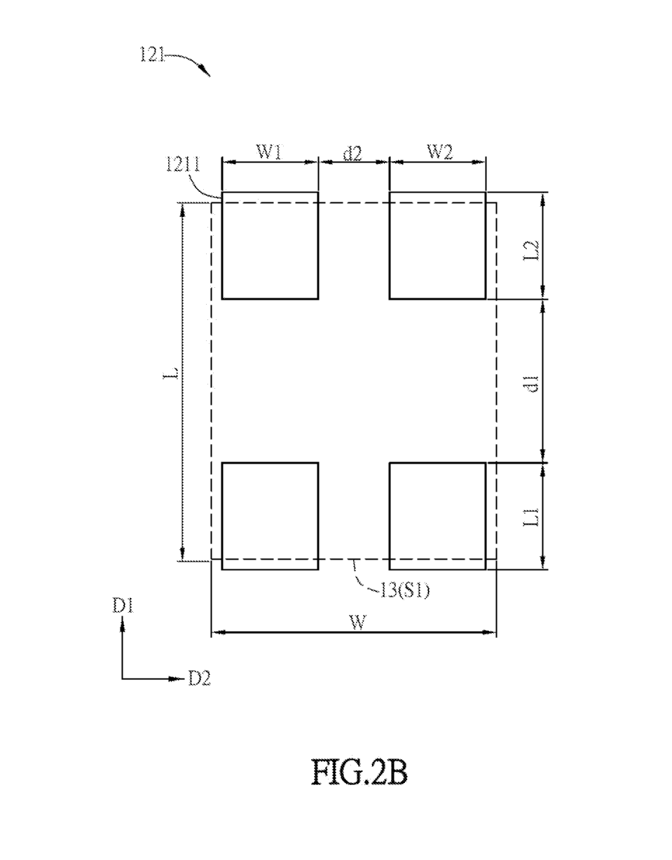

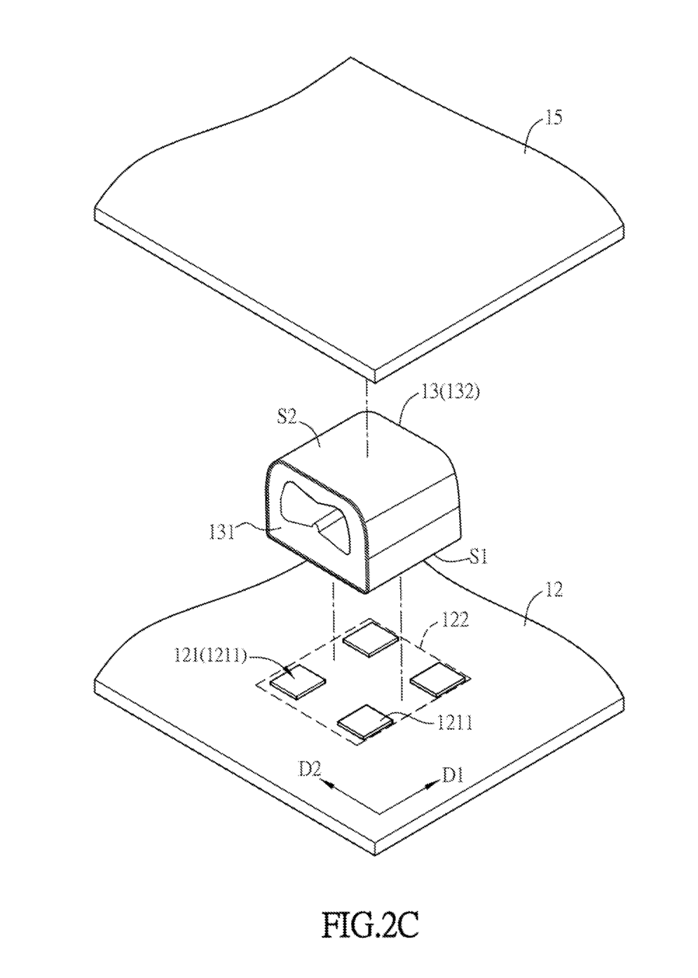

Referring to FIGS. 1 to 2C, FIG. 1 is a schematic diagram of a display device 1 according to an embodiment of the invention, FIG. 2A is a schematic diagram of the connection between the circuit board 12 and the conductive element 13 of the display device 1 in FIG. 1, FIG. 2B is a top view of the conductive pattern 121 on the circuit board 12 in FIG. 2A, and FIG. 2C is a schematic diagram of the connection of the circuit board 12, the conductive element 13, and the metal element 15 in the display device 1.

The display device 1 may be a liquid crystal display device or an organic light emitting diode display device, for example but not limited to, a display screen, a tablet computer, a smart phone, a global positioning system device, a laptop, or an electronic device having a touch screen, and it is not limited thereto.

The display device 1 includes a display panel 11, a circuit board 12, and a conductive element 13. To clearly illustrate features of the invention, in the display device 1, the extending direction of the longer side of the display panel 11 or the longer side of the circuit board 12 is defined as a first direction D1, the extending direction of the shorter side of the display panel 11 or the shorter side of the circuit board 12 is defined as a second direction D2, and the second direction D2 is substantially perpendicular to the first direction D1.

The display panel 11 may be a liquid crystal display panel (LCD) or an organic light emitting diode (OLED) display panel, and the circuit board 12 is adjacent to the display panel 11 and electrically connected to the display panel 11. The circuit board 12 may be a printed circuit board and has a control circuit or element which drives and controls the display panel 11. The circuit board 12 may be utilized to drive and control the actuation of the display panel 11 (e.g. displaying images). The circuit board 12 of the embodiment is electrically connected to the display panel 11 through two connecting circuit boards 14. Here, the connecting circuit board 14 may be, for example, a flexible printed circuit board (FPCB) or a chip on film (COF), and it is not limited thereto. Moreover, one circuit board 12 is illustrated for example in the embodiment. In various embodiments, the display device 1 may include a plurality of circuit boards 12, and the circuit boards 12 are also electrically connected to the display panel 11 through the connecting circuit board 14. In addition, in various embodiments, the display device 1 may further include a control circuit board (not shown in the figures). The control circuit board is connected to the circuit board 12, and it is electrically connected to the display panel 11 through the connecting circuit board 14 to control the actuation of the display panel 11. They are not limited thereto.

The circuit board 12 has at least a conductive pattern 121 configured at a ground zone 122. The circuit board 12 of the embodiment has four conductive patterns 121 configured at four ground zones 122 for example. Here, “the ground zone” refers to a zone to which the ground of the control element on the circuit board 12 is connected, or it may be known as the zone for disposing the ground on the circuit board 12. Therefore, the object disposed at the ground zone (the conductive pattern 121) can be directly grounded. The conductive pattern 121 may include a plurality of conductive portions 1211 spaced apart each other, and the quantities of the conductive portions 1211 respectively arranged along the first direction D1 and the second direction D2 are plural. Here, the shape of the conductive portion 1211 may be, for example, a polygonal, circular, curved or irregular shape. As shown in FIG. 2A, the quantity of the conductive portions 1211 of the embodiment is four, and the shape of the conductive portion 1211 is a quadrilateral for example. Because the first direction D1 is substantially perpendicular to the second direction D2, two conductive portions 1211 are arranged along the first direction D1, and two conductive portions 1211 are arranged along the second direction D2 so as to form a two-dimensional matrix. However, in various embodiments, the quantity of the conductive portions 1211 may be also, for example but not limited to, six, eight, etc., and they may be also arranged in a two-dimensional matrix.

The conductive element 13 and the conductive pattern 121 are correspondingly disposed, and it is disposed on the conductive pattern 121. The conductive element 13 has elasticity itself, so it has resilience to provide buffer force when taking force. Moreover, “correspondingly disposed” refers to that the quantity of the conductive patterns 121 is equal to that of the conductive elements 13, one conductive element 13 is disposed on one conductive pattern 121, and it directly contacts and is electrically connected to the conductive portions 1211, so that the conductive element 13 is grounded the same as the conductive portions 1211. Furthermore, at least a part of the conductive portions 1211 are directly connected to the conductive element 13 by welding. In the embodiment, four conductive portions 1211 are all connected to the conductive element 13 by welding (namely they are connected by welding), which results in that the conductive portions 1211 contact and are electrically connected to the conductive element 13. It not only improves the strength of connecting the conductive element 13 and the conductive portions 1211 but also reduces the contact impedance between them. The conductive element 13 of the embodiment may be also known as the solderable conductive element 13.

The sectional shape of the conductive element 13 may be quadrilateral (trapezoidal, square, or rectangular), curved, or elliptical, and it is not limited thereto. Moreover, the conductive element 13 of the embodiment has an elastic body 131 and a metal layer 132, and the metal layer 132 is disposed on the outer surface of the elastic body 131 to cover the outer peripheral edge of the elastic body 131. Thus, the metal layer 132 may directly contact the conductive portions 1211 and be electrically connected. Further, the elastic body 131 is a hollow elastomer and may be formed by insulation materials (e.g. polymers, rubber, or silicone) or conductive materials (e.g. polymers incorporated with conductive particles), and it is not limited thereto. In addition, the material of the metal layer 132 may be formed by, for example, a single layer metal material of tin, copper, or aluminum (aluminum can enhance the resistance to stress) or multilayer metal composite material, and it is not limited thereto either.

Further, the conductive element 13 has a first surface S1 and a second surface S2, the first surface S1 contacts the conductive portions 1211, and the second surface S2 is opposite to the first surface S1. As shown in FIG. 2B, in the embodiment, the length L of the first surface S1 of the conductive element 13 along the first direction D1 is 5 mm for example, the width W of the first surface S1 along the second direction D2 is 4 mm for example, and its height is 3 mm for example (not indicated in the figure). Moreover, the sum of the lengths (L1+L2) of the conductive portions 1211 along the first direction D1 is 0.5 to 0.85 times of the length L of the first surface S1 of the conductive element 13 along the first direction D1. An interval d1 between two adjacent conductive portions 1211 along the first direction D1 is larger than 0.5 mm. In the conductive portions 1211 of the conductive pattern 121 according to the embodiment, the length L1 along the first direction D1 is 1.5 mm, the length L2 is also 1.5 mm, the length L is 5 mm, and therefore (L1+L2)/L=0.6. Moreover, the interval d1 between two adjacent conductive portions 1211 along the first direction D1 is 2.3 mm, and 1.5+2.3+1.5=5.3>5, so that at least one of the conductive portions 1211 is partially exposed outside the conductive element 13 in the first direction D1. Here, two conductive portions 1211 are both partially exposed outside the first surface S1 of the conductive element 13 in the first direction D1.

In addition, in the embodiment, the widths W1 and W2 of the conductive portions 1211 along the second direction D2 are respectively 1.35 mm, the interval d2 between two adjacent conductive portions 1211 along the second direction D2 is 1.0 mm (1.35+1.0+1.35=3.7 mm), and the width W of the conductive element 13 along the second direction D2 is 4 mm (4>3.7). Therefore, the conductive portions 1211 are completely covered (not exposed) with the conductive element 13 in the second direction D2, thereby, resulting in that the conductive element 13 has relatively high connection strength when connected to the conductive portions 1211, and therefore it can bear relatively high lateral push stress in the second direction D2 without falling off.

As shown in FIG. 2C, the display device 1 may further include a metal element 15. The metal element 15 may be a case, a frame or a backplane (for example an element of a backlight module) of the display device 1, and the metal element 15 contacts the second surface S2. Therefore, the ground of the element on the circuit board 12 may be electrically connected to the metal element 15 through the conductive element 13. Accordingly, when EMI and/or ESD occur on the circuit board 12, the EMI and/or ESD charges may be transferred to the metal element 15 of the display device 1 through the conductive element 13 to thereby improve the protection of the circuit board 12 from EMI or ESD.

Moreover, during the display device 1 is assembled or transported, the metal element 15 mainly generates the stress due to the lateral force (may refer to shear stress) along the second direction D2 to the conductive element 13. The quantities of the conductive portions 1211 respectively arranged along the first direction D1 and the second direction D2 are plural and the conductive element 13 is connected to the conductive portions 1211 by welding, which may allow the conductive pattern 121 and the conductive element 13 being electrically connected to reduce the ground impedance and improve the durability of the conductive element 13 and the circuit board 12 against the stress due to the lateral force. Thus, compared with conventional technology, the display device 1 can avoid poor contact, separation, or other problems of the conductive element 13 so as to improve the protection against EMI and ESD.

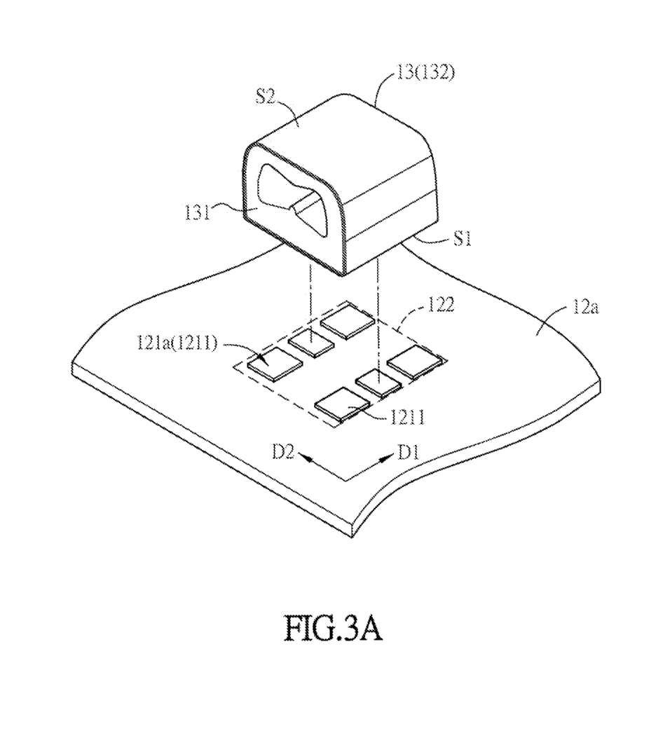

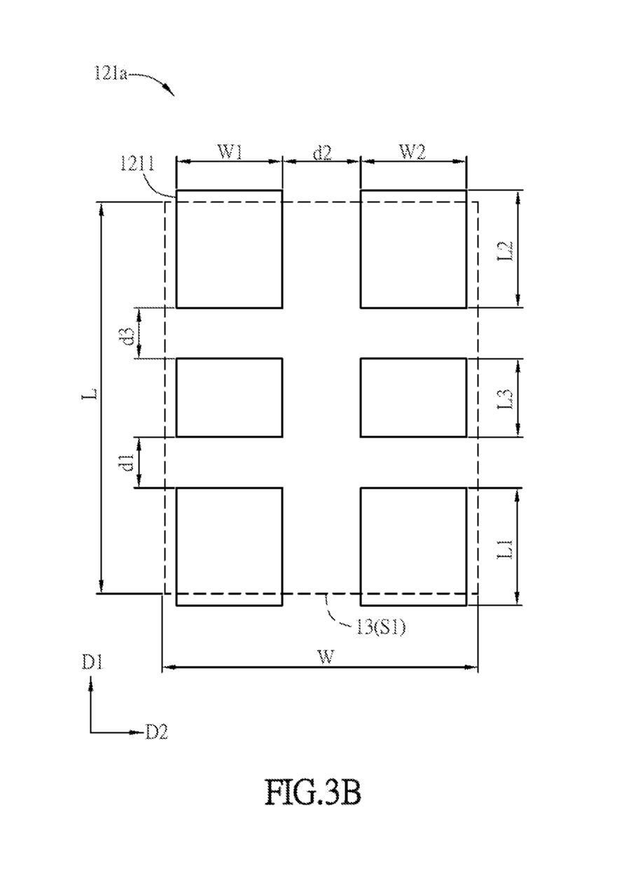

Referring to FIGS. 3A and 3B, FIG. 3A is a schematic diagram of the connection between the circuit board 12a and the conductive element 13 of another embodiment, and FIG. 3B is a top view of the conductive pattern 121a on the circuit board 12a in FIG. 3A.

The main difference from FIGS. 2A and 2B is that, in the embodiment, the quantity of the conductive portions 1211 of the conductive pattern 121a on the circuit board 12a is 6, and they are arranged in a two-dimensional matrix (arranged in two rows, and each row has three conductive portions 1211). In addition, as shown in FIG. 3, in the conductive portions 1211 of the embodiment, the length L1 along the first direction D1 is 1.5 mm, the length L2 is also 1.5 mm, but the length L3 of the other conductive portion 1211 located between two conductive portions 1211 whose lengths are 1.5 mm is only 1.0 mm. The length L of the first surface S1 along the first direction D1 is also 5 mm, so (L1+L2+L3)/L=0.8. Moreover, the intervals d1 and d3 between two adjacent conductive portions 1211 along the first direction D1 are both equal to 0.65 mm, so the interval d1 (or d3) between two adjacent conductive portions 1211 along the first direction D1 is larger than 0.5 mm and smaller than 1.2 mm (0.5 mm<d1<1.2 mm) in the embodiment. Besides, two conductive portions 1211 are also partially exposed outside the first surface S1 of the conductive element 13 in the first direction D1.

Further, in the embodiment, the widths W1 and W2 of the conductive portions 1211 along the second direction D2 are also 1.35 mm, and the interval d2 between two adjacent conductive portions 1211 along the second direction D2 is also 1.0 mm, so W1+d2+W2=3.7 mm. The width W of the conductive element 13 along the second direction D2 is also 4 mm (4>3.7), and therefore the conductive portions 1211 are completely covered with the conductive element 13 in the second direction D2.

It should be noted that, in the embodiment, in the two rows of the conductive portions 1211 along the first direction D1, the four outside conductive portions 1211 may be also connected to the conductive element 13 by welding. However, two conductive portions 1211 in the middle may be connected to the conductive element 13 by welding or adhesion. If the two conductive portions 1211 in the middle are connected to the conductive element 13 by adhesion, it contributes to lower ground impedance (due to a larger contact area) in comparison with the embodiment of FIG. 2A. If the two conductive portions 1211 in the middle are connected to the conductive element 13 by welding, it contributes to lower ground impedance and higher connection strength in comparison with the embodiment of FIG. 2A.

It should be mentioned that when the same amount of stress due to the lateral force occurs in the conductive element 13 along the second direction D2 for the same times, the embodiment has relatively low contact impedance in comparison with conventional technology. Additionally, compared with conventional technology which only has one conductive portion along the first direction D1, if the stresses due to lateral forces occur for the same times, a lower contact impedance is similarly obtained and it needs more times to cause the poor contact or separation of the conductive element 13 by the stresses of due to lateral forces in the embodiment. Thus, compared with conventional technology, the contact impedance between the conductive element 13 and the circuit board 12 can be reduced, and the durability of the conductive element 13 against the stress due to the lateral force can be also improved in the embodiment. Therefore, when the stress due to the lateral force occurs, a broken circuit which results from the fracture or separation of the surface connecting the conductive element 13 and the circuit board 12 can be improved to enhance the protection against EMI and ESD.

In summary, in the display device according to the invention, the quantities of the conductive portions which are spaced apart each other and located at the ground zone of the circuit board respectively along the first direction and the second direction are plural, and the conductive element is disposed on the conductive pattern and electrically connected to the conductive portions. Thus, compared with conventional technology, it can reduce the ground impedance of the conductive element and the ground zone and improve the durability of the conductive element against the stress due to the lateral force. Therefore, it can avoid poor contact, separation, or other problems of the conductive element so as to improve the protection of the display device from EMI and ESD.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A display device, comprising:
a display panel;
a circuit board, adjacent to the display panel and electrically connected to the display panel, wherein the circuit board has at least a conductive pattern configured at a ground zone, the conductive pattern has a plurality of conductive portions spaced apart each other, the quantities of the conductive portions respectively arranged along a first direction and a second direction are plural, and the first direction is substantially perpendicular to the second direction; and
a conductive element, disposed on the conductive pattern, wherein the conductive element is electrically connected to the conductive portions.

2. The display device of claim 1, wherein the conductive portions are arranged in a two-dimensional matrix.

3. The display device of claim 1, wherein at least a part of the conductive portions are directly connected to the conductive element by welding.

4. The display device of claim 1, wherein the conductive element has an elastic body and a metal layer, and the metal layer is disposed on an outer surface of the elastic body.

5. The display device of claim 1, wherein the conductive element has a first surface, the first surface contacts the conductive pattern, and the sum of the lengths of the conductive portions along the first direction is 0.5 to 0.85 times of the length of the first surface along the first direction.

6. The display device of claim 1, wherein an interval between two adjacent conductive portions along the first direction is larger than 0.5 mm and smaller than 1.2 mm.

7. The display device of claim 1, wherein at least one of the conductive portions is partially exposed outside the conductive element in the first direction.

8. The display device of claim 1, wherein the conductive portions are completely covered with the conductive element in the second direction.

9. The display device of claim 1, further comprising:
a metal element, wherein the conductive element has a first surface and a second surface opposite to the first surface, the first surface contacts the conductive portions, and the second surface contacts the metal element.

10. The display device of claim 9, wherein the metal element is a case, a frame or a backplane of the display device.
